(19) United States
(12) Patent Application Publication
(10) Pub. No.: US 2015/0263000 A1
(43) Pub. Date: Sep. 17, 2015

(54) SEMICONDUCTOR DEVICE

(71) Applicant: Kabushiki Kaisha Toshiba, Tokyo (JP)

(72) Inventors: Hiroshi Kono, Himeji Hyogo (JP); Kazuto Takao, Tsukuba Ibaraki (JP)

(21) Appl. No.: 14/465,583

(22) Filed: Aug. 21, 2014

(30) Foreign Application Priority Data
Mar. 13, 2014 (JP) 2014-049955

(51) Int. Cl. H01L 27/07; H01L 49/02; H01L 29/78

(52) U.S. Cl. CPC H01L 27/0733; H01L 29/7803; H01L 28/60

(57) ABSTRACT

According to one embodiment, semiconductor device includes: a first semiconductor region of a first conductive type; a second semiconductor region of a second conductive type provided on the first semiconductor region; a third semiconductor region of the first conductive type provided on the second semiconductor region, the third semiconductor region having a higher impurity concentration than the impurity concentration of the first semiconductor region; a third electrode in contact with the third semiconductor region, the second semiconductor region, and the first semiconductor region via a first dielectric film; and a capacitance element unit having a fourth electrode provided above the second semiconductor region, a fifth electrode provided above the fourth electrode, and a second dielectric film provided between the fourth electrode and the fifth electrode.

### CROSS-REFERENCE TO RELATED APPLICATIONS

This application is based upon and claims the benefit of priority from Japanese Patent Application No. 2014-049955, filed on Mar. 13, 2014; the entire contents of which are incorporated herein by reference.

### FIELD

Embodiments described herein relate generally to a semiconductor device.

### BACKGROUND

When a switching element such as a MOSFET is used in an electronic circuit such as an inverter circuit, charging a feedback capacitance for operation of the switching element may sometimes increase the potential of a gate electrode of the switching element, which may cause a misoperation of the switching element.

Various methods may be applied in order to prevent such a misoperation, including a method for supplying a lower potential than a threshold potential to a gate electrode when the switching element is in an off state, a method for establishing a short circuit with a low impedance between a gate electrode and a source electrode when the switching element is in an off state, and a method for connecting an external capacitor in between a gate electrode and a source electrode.

These methods, however, may require an additional special electronic circuit, which may increase the cost. Due to a voltage drop of a gate wire connected to a gate electrode, such a potential increase of the gate electrode may not be prevented sufficiently, by which a misoperation may not be prevented therefore.

### BRIEF DESCRIPTION OF THE DRAWINGS

FIG. 1 is a schematic section view showing a semiconductor device according to a first embodiment;

FIG. 2 is a schematic plan view showing a semiconductor device according to the first embodiment;

FIG. 3 is a circuit diagram showing an example of an electronic circuit including a MOSFET;

FIG. 4A and FIG. 4B are circuit diagrams showing examples of an electronic circuit including a MOSFET;

FIG. 5 is a circuit diagram showing an example of an electronic circuit having a semiconductor device according to the first embodiment;

FIG. 6 is a section view schematically showing a semiconductor device according to a second embodiment; and

FIG. 7 is a partially enlarged section view schematically showing a part of the semiconductor device according to the second embodiment.

### DETAILED DESCRIPTION

According to one embodiment, a semiconductor device includes: a first semiconductor region of a first conductive type; a second semiconductor region of a second conductive type provided on the first semiconductor region; a third semiconductor region of the first conductive type provided on the second semiconductor region, the third semiconductor region having a higher impurity concentration than the impurity concentration of the first semiconductor region; a third electrode in contact with the third semiconductor region, the second semiconductor region, and the first semiconductor region via a first dielectric film; and a capacitance element unit having a fourth electrode provided above the second semiconductor region, a fifth electrode provided above the fourth electrode, and a second dielectric film provided between the fourth electrode and the fifth electrode. Embodiments will be described below with reference to drawings. Like numbers refer to like parts throughout, and repetitive description for the members which have been described once will be omitted. The following embodiments may be applied in combination.

### First Embodiment

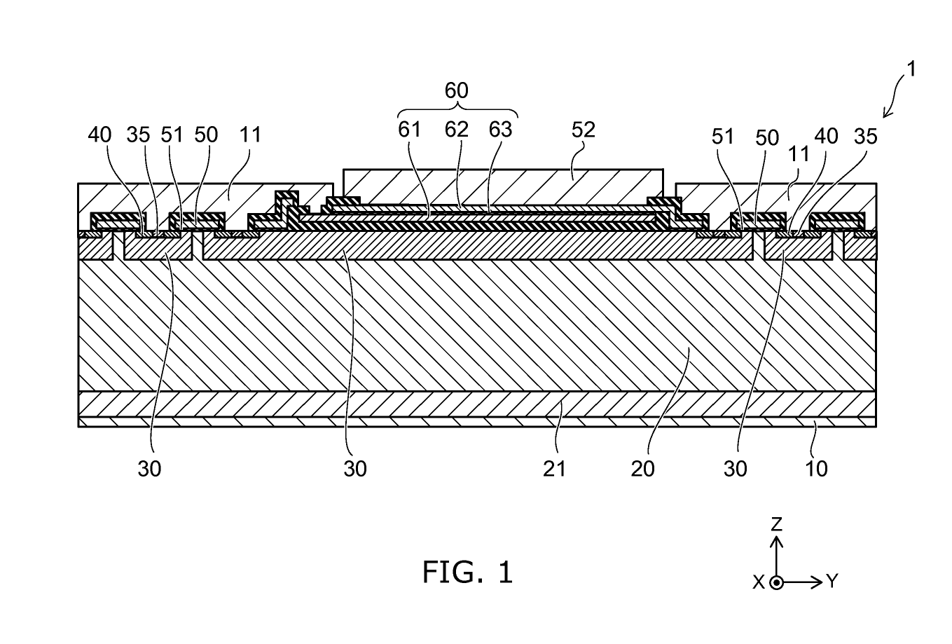

FIG. 1 is a schematic section view showing a semiconductor device according to the first embodiment.

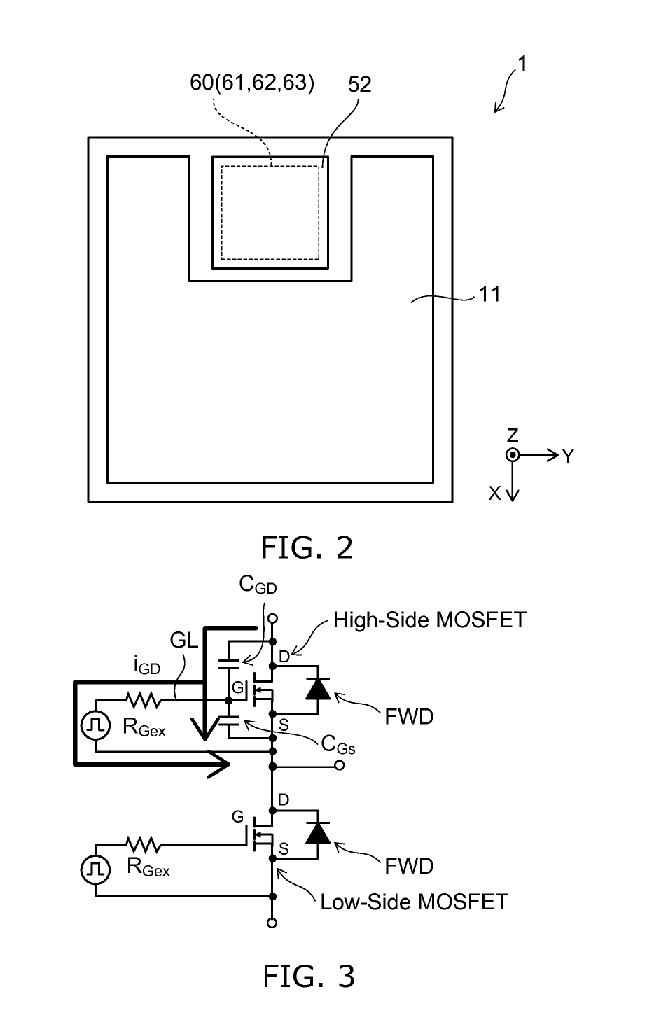

FIG. 2 is a schematic plan view showing a semiconductor device according to the first embodiment.

Here, FIG. 1 shows a cross-section view of a part of the semiconductor device, and FIG. 2 shows a plane of a chip-shaped semiconductor device 1.

The semiconductor device 1 shown in FIG. 1 may be a MOSFET (Metal Oxide Semiconductor Field Effect Transistor) having an upper/lower electrode structure internally including a capacitance element between a gate and a source.

The semiconductor device 1 comprises a drain electrode 10 (first electrode) and a source electrode 11 (second electrode) which are aligned in a Z-direction. An n-type drift region 20 (first semiconductor region) is provided between the drain electrode 10 and the source electrode 11. An n⁺-type drain region 21 is provided between the drain electrode 10 and the drift region 20.

A p-type base region 30 (second semiconductor region) is provided between the drift region 20 and the source electrode 11. An n⁺-type source region 40 (third semiconductor region) is provided between the base region 30 and the source electrode 11. The source region 40 has a higher impurity concentration than the impurity concentration of the drift region 20. A p⁺-type contact region 35 is provided between the base region 30 and the source electrode 11. The contact region 35 has a higher impurity concentration than the impurity concentration of the base region 30.

A gate electrode 50 (third electrode) is in contact with the source region 40, base region 30, and drift region 20 via a gate dielectric film 51 (first dielectric film). The gate electrode 50 is positioned under the source electrode 11.

A capacitance element unit 60 is provided above the drift region 20 where the source electrode 11 is not disposed. The capacitance element unit 60 includes an electrode 61 (the fourth electrode), an electrode 62 (fifth electrode), and a dielectric film 63 (second dielectric film) provided between the electrode 61 and the electrode 62. The electrode 61 is electrically connected to the source electrode 11. The electrode 62 is electrically connected to the gate electrode 50. The electrode 61 and the electrode 62 may be reversed vertically.

An electrode pad (gate pad) 52 electrically connected to the gate electrode 50 is aligned with the source electrode 11 above the drift region 20. For example, the electrode 62 electrically connected to the gate electrode 50 may be provided below the electrode pad 52. The capacitance element unit 60 is provided below the electrode pad 52. It should be noted that the electrode 62 and the electrode pad 52 may be electrically connected via a wire, not shown, in a case where the electrode 61 is provided above the electrode 62.

The p-type base region 30 and the n-type drift region 20 construct an internal diode (free-wheel diode). It should be noted that the free-wheel diode may be a Schottky Barrier diode (SBD) or may be an external diode.

The electrode 61 and electrode 62 included in the capacitance element unit 60 extend in an X-direction (second direction) which intersects with a Z-direction (first direction) from the drain electrode 10 to the source electrode 11 and a Y-direction(third direction) which intersects with the Z-direction and X-direction (see FIG. 2).

A planer structure of the capacitance element unit 60 is shown for exemplary purpose. The planer area may be adjusted properly to properly adjust the capacitance of the capacitance element unit 60 with a high margin width. The capacitance element unit 60 disposed below the electrode pad 52 may suppress an increase of the chip area.

The n⁺-type and n-type may be called a first conductive type, and the p⁺-type and p-type may be called a second conductive type. Here, the impurity concentration decreases in order of n⁺-type and n-type and in order of p⁺-type and p-type.

The term “impurity concentration” may refer to an effective concentration of an impurity element that contributes to conductivity of a semiconductor material. For example, in a case where a semiconductor material includes a donor impurity element and an acceptor impurity element, a concentration acquired by subtracting an offset between the donors and the acceptors from the activating impurity elements may correspond to the impurity concentration.

The principal ingredients of the drift region 20, drain region 21, base region 30, source region 40, and contact region 35 may be, for example, silicon carbide (SiC), silicon (Si), or the like. The electrode 61 may include polysilicon, for example. The electrode 62 may include polysilicon, for example.

In a case where the main ingredient of a semiconductor material of the semiconductor device 1 is silicon carbide (SiC), an impurity element of a first conductive type may be nitrogen (N), phosphorus (P) or the like, for example. An impurity element of a second conductive type may be aluminum (Al), boron (B) or the like, for example.

In a case where the main ingredient of a semiconductor material of the semiconductor device 1 is silicon (Si), an impurity element of a first conductive type may be phosphorus (P), arsenic

(As) or the like, for example. An impurity element of a second conductive type may be boron (B) or the like, for example.

The gate electrode 50 may include polysilicon and/or metal including an impurity element. In an embodiment, a dielectric film includes silicon oxide (SiOₓ), silicon nitride (SiNₓ) or the like, for example. However, the dielectric film 63 may include a high-k material.

Before describing effects of the semiconductor device 1, operations to be performed by an electronic circuit including a MOSFET that is a switching element will be described.

FIG. 3 is a circuit diagram showing an example of an electronic circuit including a MOSFET.

FIG. 3 shows an example of an inverter circuit in which a high-side MOSFET and a low-side MOSFET are connected in series. In FIG. 3, gates, sources and drains of the MOSFETs are indicated by “G”, “5”, and “D”, respectively.

It is assumed here that the low-side MOSFET has an off state while the high-side MOSFET is being changed from an on state to an off state. Immediately after that, reflux current is fed to a high-side free-wheel diode (FWD) for a while. In this case, Vf beyond a junction barrier of the high-side free-wheel diode FWD is being applied to between the source electrode (S) and drain electrode (D) of the high-side MOSFET.

Next, the low-side MOSFET is changed to an on state. Thus, the high-side source voltage drops to an ON voltage (Vₒₙ) of the low-side MOSFET. In this case, the high-side source-drain voltage rises to voltage (V_{cc}⁻Vₒₙ). With this, the feedback capacitance (C_{SD}) is charged, and charge current (Ig) is fed to the gate electrode. Here, because gate line (GL) has a resistance R_{Gex}, the voltage drop may increase the potential of the gate electrode (G) of the high-side MOSFET. When the potential exceeds a threshold potential (Vth) of the gate electrode (G), the high-side MOSFET is changed to an on state, that is, a misoperation of the gate electrode occurs.

In order to avoid such a misoperation, the following method may be applied.

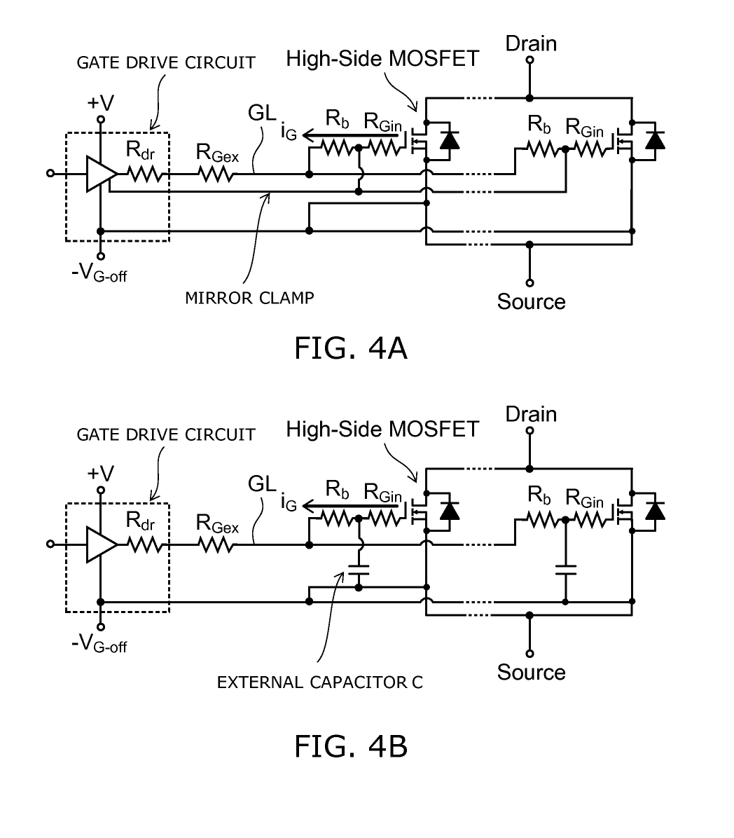

FIG. 4A and FIG. 4B are circuit diagrams showing examples of an electronic circuit including a MOSFET.

R_{Gin} indicates an internal resistance of the MOSFET, and R_{b} indicates a resistance between the internal resistance and a gate line (GL). R_{dr} indicates a resistance within a gate drive circuit. Current i_{G} indicates current fed from the MOSFET to the gate drive circuit.

First, both of the electronic circuits shown in FIGS. 4A and 4B have a gate drive circuit that is controllable such that the gate electrode (G) has a negative potential when the MOSFET has an off state. The gate drive circuit is controlled by applying negative voltage to the gate electrode (G) when the MOSFET has an off state so that V_{GS} does not exceed a threshold potential (Vth).

However, application of negative voltage to the gate electrode may cause an increase of the cost of the gate drive circuit, compared with driving through application of positive voltage only.

In order to further avoid an increase of the potential of the gate electrode (G), a mirror clamp may be mounted which is configured to establish a short circuit with a low impedance between the gate electrode (G) and the source electrode (S) when the high-side MOSFET has an off state, for example, as shown in FIG. 4A.

In this case, however, a gate drive circuit for the mirror clamp may be needed, which may increase the cost. The current i_{G} may cause a voltage drop in the gate line (GL), sometimes resulting in an increase of the potential of the gate electrode (G) when the MOSFET has an off state. Eventually, in some cases, the configuration in FIG. 4A does not allow sufficient exhibition of the effect of the mirror clamp, which may not prevent a misoperation.

Alternatively, in order to prevent an increase of the potential of the gate electrode (G), an external capacitor (C) may be connected in parallel between the gate electrode (G) and the source electrode (S) as shown in FIG. 4B.

In this case, however, the mounting of the external capacitor (C) may increase the mounting area. Furthermore, some external capacitors (capacitor chips) may not have sufficient heat-resistance. The current i_{G} may cause a voltage drop in the gate line (GL), and the potential of the gate electrode (G) may increase when the MOSFET has an off state, which does not allow prevention of a misoperation.

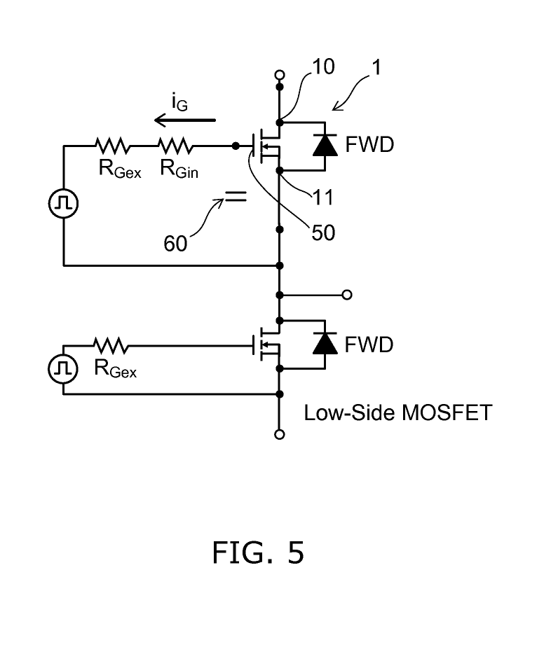

In contrast, FIG. 5 is a circuit diagram showing an example of an electronic circuit having a semiconductor device according to the first embodiment.

In the semiconductor device 1, the capacitance element unit 60 is disposed immediately near the gate electrode 50 or immediately near the source electrode 11. Thus, even when the current i_{G} flows and a voltage drop occurs in the gate line, a charge storage effect in the capacitance element unit 60 disposed immediately near the gate electrode 50 or immediately near the source electrode 11 may securely prevent a potential increase of the gate electrode 50, which may securely prevent a misoperation.

The capacitance element unit 60 is internally included in the semiconductor device 1 and is not an external capacitor. This may prevent the increase of the mounting area in the semiconductor device 1. In other words, an another element may be mounted in an region where an external capacitor is to be disposed, achieving high density mounting. This may further prevent an increase of the cost.

The capacitance element unit 60 may be formed through a wafer process along with the MOSFET. Thus, the dielectric film 63 between the electrodes 61 and 62 may have substantially equal tolerance (breakdown voltage tolerance, high temperature tolerance) to that of the gate dielectric film 51, for example. The semiconductor device 1 internally includes the capacitance element unit 60 without changing dimensions (such as a width in the Y-direction) of the existing MOSFETs. In other words, the pitch between the MOSFETs does not change.

### Second Embodiment

The position of the capacitance element unit is not limited to the example described above.

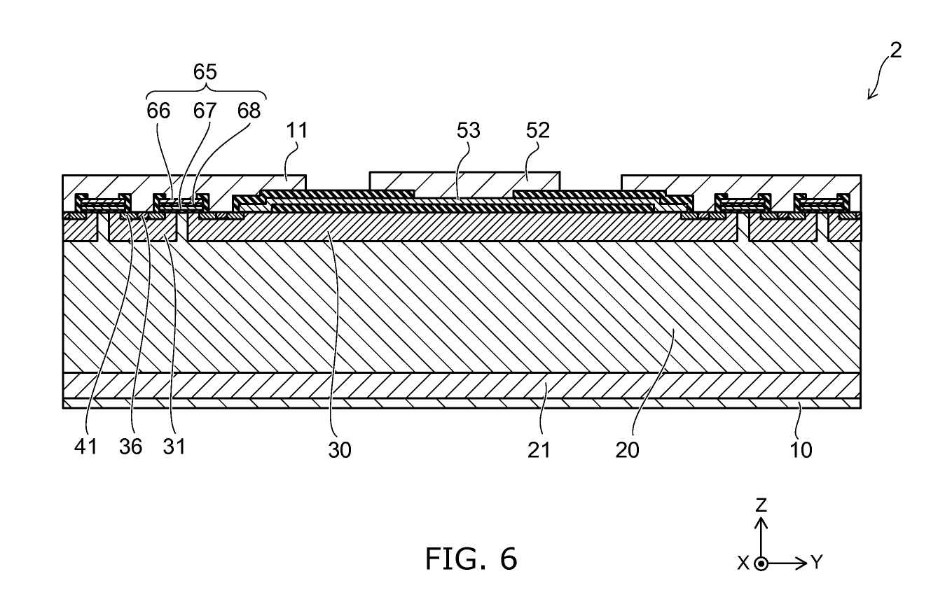

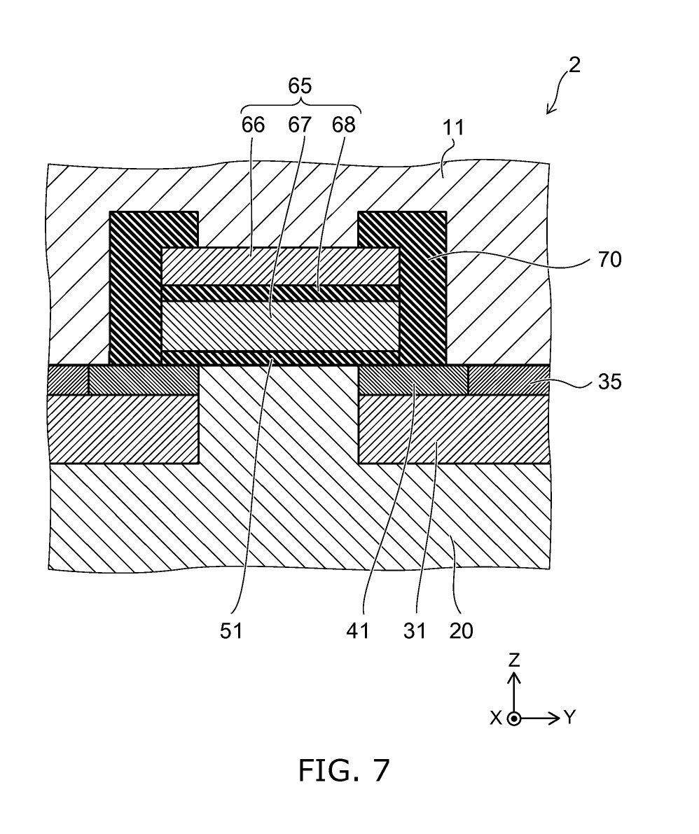

FIG. 6 is a section view schematically showing a semiconductor device according to a second embodiment. FIG. 7 is a partially enlarged section view schematically showing a part of the semiconductor device according to the second embodiment. A semiconductor device 2 has a p-type semiconductor region 31 (fourth semiconductor region), an n⁺-type semiconductor region 41 (fifth semiconductor region), and a p⁺-type semiconductor region 36, in addition to the drift region 20, drain region 21, base region 30, source region 40, and contact region 35 which are described above. In the semiconductor device 2, a capacitance element unit 65 is disposed at the position where the gate electrode 50 is disposed in the semiconductor device 1.

Here, the semiconductor region 31 is provided between the drift region 20 and the source electrode 11. The semiconductor region 31 is formed simultaneously with the formation of the base region 30 through a wafer process. The semiconductor region 41 is provided between the semiconductor region 31 and the source electrode 11. The semiconductor region 41 has a higher impurity concentration than the impurity concentration of the drift region 20. The semiconductor region 41 is formed simultaneously with the formation of the source region 40 through a wafer process.

The semiconductor region 36 is formed simultaneously with the formation of the contact region 35 through a wafer process. The dielectric film 51 is formed simultaneously with the formation of the gate dielectric film 51 through a wafer process.

In the semiconductor device 2, the capacitance element unit 65 is in contact with the semiconductor region 41, semiconductor region 31, and drift region 20 via the dielectric film 51. A side wall-protection film 70 is provided on a side wall of the capacitance element unit 65.

The capacitance element unit 65 has an electrode 66 (fifth electrode), an electrode 67 (fourth electrode) and a dielectric film 68 (second dielectric film). The electrode 66 is electrically connected to the source electrode 11. In the semiconductor device 2, the electrode 66 is directly in contact with the source electrode 11. The electrode 67 is electrically connected to the gate electrode 50 via a wire (not shown). The dielectric film 68 is provided between the electrode 66 and the electrode 67. The electrode 66 may include polysilicon, for example. The electrode 67 may include polysilicon, for example. The dielectric film 68 may include a high-k material.

This structure in which the capacitance element unit 65 is provided immediately near the gate electrode 50 or immediately near the source electrode 11 may also provide similar effects to those of the first embodiment. In the semiconductor device 2, the electrode 66 including polysilicon is provided between the dielectric film 68 and the source electrode 11. This allows the electrode 66 to serve as a barrier layer to prevent metal diffusion from the source electrode 11 to the dielectric film 68. In other words, the semiconductor device may be highly reliable.

In the semiconductor devices 1 and 2, a p⁺-type collector region may be provided between the drain region 21 and drain electrode 10 to serve as an IGBT. The electrodes 61, 62, 66, or 67, or gate electrode 50 may include polysilicon, poly silicon carbide, metal silicide, or a stacked body of polysilicon carbide and metal silicide. In other words, the electrode 61, 62, 66, or 67 or gate electrode 50 may include at least one of polysilicon, polysilicon carbide, and metal silicide or a stacked body of at least two of polysilicon, polysilicon carbide, and metal silicide.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region of a first conductive type;
a second semiconductor region of a second conductive type provided on the first semiconductor region;
a third semiconductor region of the first conductive type provided on the second semiconductor region, the third semiconductor region having a higher impurity concentration than the impurity concentration of the first semiconductor region;
a third electrode in contact with the third semiconductor region, the second semiconductor region, and the first semiconductor region via a first dielectric film; and
a capacitance element unit having a fourth electrode provided above the second semiconductor region, a fifth electrode provided above the fourth electrode, and a second dielectric film provided between the fourth electrode and the fifth electrode.

2. The device according to claim 1, further comprising:
a first electrode; and
a second electrode,
the first semiconductor region being provided between the first electrode and the second electrode;
the second semiconductor region being provided between the first semiconductor region and the second electrode;
the third semiconductor region being provided between the second semiconductor region and the second electrode;
a fourth electrode being electrically connected to the second electrode, and
a fifth electrode being electrically connected to the third electrode.

3. The device according to claim 2, wherein the capacitance element unit is provided above the first semiconductor region where the second electrode is not disposed,

4. The device according to claim 1, further comprising an electrode pad provided above the first semiconductor region, the electrode pad being electrically connected to the third electrode.

5. The device according to claim 4, wherein the capacitance element unit is provided below the electrode pad.

6. The device according to claim 2, wherein the fourth electrode and the fifth electrode extend in a second direction and a third direction, the second direction intersecting with a first direction from the first electrode to the second electrode, the third direction intersecting with the first direction and the second direction.

7. The device according to claim 2, wherein a part of the second electrode is in contact with a part of the fourth electrode.

8. The device according to claim 1, wherein the fourth electrode includes at least one of polysilicon, polysilicon carbide, and metal silicide or a stacked body of at least two of polysilicon, polysilicon carbide, and metal silicide.

9. The device according to claim 1, wherein the fifth electrode includes at least one of polysilicon, polysilicon carbide, and metal silicide or a stacked body of at least two of polysilicon, polysilicon carbide, and metal silicide.

10. The device according to claim 1, wherein the fourth electrode being in contact with the first semiconductor region and the third semiconductor region via a third dielectric film.

11. The device according to claim 10, wherein the fifth electrode is in contact with the second electrode.

12. The device according to claim 10, wherein the fourth electrode includes at least one of polysilicon, polysilicon carbide, and metal silicide or a stacked body of at least two of polysilicon, polysilicon carbide, and metal silicide.

13. The device according to claim 11, wherein the fifth electrode includes at least one of polysilicon, polysilicon carbide, and metal silicide or a stacked body of at least two of polysilicon, polysilicon carbide, and metal silicide.
